(19) United States
(12) Patent Application Publication
(10) Pub. No.: US 2026/0129898 A1
(43) Pub. Date: May 7, 2026

(54) SEMICONDUCTOR DEVICE AND METHODS FOR FORMING THE SAME

(71) Applicant: Vanguard International Semiconductor Corporation, Hsinchu (TW)

(72) Inventors: Yi-Wei LIEN, Hsinchu (TW); Hsin-Chang TSAI, Kaohsiung City (TW)

(73) Assignee: Vanguard International Semiconductor Corporation, Hsinchu (TW)

(21) Appl. No.: 18/935,087

(22) Filed: Nov. 1, 2024

(51) Int. Cl. H01L 29/778; H01L 29/06; H01L 29/20; H01L 29/423; H01L 29/66

(52) U.S. Cl. CPC H10D 30/4755; H10D 30/015; H10D 62/113; H10D 62/126; H10D 62/8503; H10D 64/513; H10D 64/518

(57) ABSTRACT

A semiconductor device includes a substrate, a seed layer on the substrate, an epitaxy stack on the seed layer, and a gate structure on the epitaxy stack. The semiconductor device further includes a source structure and a drain structure on opposite sides of the gate structure, respectively. The semiconductor device further includes an isolation region corresponding to an end region of the gate structure. The isolation region is adjacent to the end region of the gate structure. The isolation region is positioned outside the end region of the gate structure. The isolation region is not in contact with the gate structure.

### BACKGROUND

### Technical Field

The present disclosure relates to a semiconductor device and methods for forming the same, and in particular, it relates to a semiconductor device and methods for effectively improving the electrical performance of the semiconductor device.

### Description of the Related Art

In recent years, there has been rapid development in semiconductor devices for use in the fields of computers and consumer electronics, among other fields. Currently, semiconductor device technology in the product market for metal-oxide-semiconductor field-effect transistors (MOSFETs) has been widely accepted and held a significant market share. Semiconductor devices are used in various electronic applications, such as high-power devices, personal computers, mobile phones, digital cameras, and the like. These semiconductor devices are typically fabricated by depositing an insulating or dielectric material, a conductive material, or a semiconductor material on a substrate, followed by patterning the various material layers using lithography and etching processes. Therefore, circuit devices and components may be formed on the substrate.

Among these devices, high-electron mobility transistors (HEMTs) have certain advantages, including high output power and high breakdown voltage, and thus they are widely used in high-power applications. Even though existing semiconductor devices have generally been adequate for their intended purposes, they have not been entirely satisfactory in all respects. There are still issues regarding their structure and manufacture methods that still need to be addressed.

### SUMMARY

An embodiment of the present disclosure provides a semiconductor device, the semiconductor device includes: a substrate; a seed layer on the substrate; an epitaxial stack on the seed layer; and a gate structure on the epitaxial stack. The semiconductor device further includes: a source structure and a drain structure on opposite sides of the gate structure, respectively; and an isolation region corresponding to an end region of the gate structure. The isolation region is positioned outside the end region of the gate structure, and the isolation region is not in contact with the gate structure.

Another embodiment of the present disclosure provides a method for forming a semiconductor device, the method includes: providing a substrate; forming a seed layer on the substrate; forming an epitaxial stack on the seed layer; and forming a gate structure on the epitaxial stack. The method further includes: forming an isolation region corresponding to an end region of the gate structure; and forming a source structure and a drain structure on opposite sides of the gate structure, respectively. The isolation region is positioned outside the end region of the gate structure and is not in contact with the gate structure from a top view above the substrate.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 is a top view of a semiconductor device, according to some embodiments of the present disclosure.

FIG. 2 is a partial top view of another semiconductor device, according to some embodiments of the present disclosure.

FIG. 3 is a cross-sectional view of a semiconductor device, according to some embodiments of the present disclosure.

FIGS. 4A-4D are cross-sectional views of the semiconductor device illustrated in FIG. 3 at various intermediate stages, according to some embodiments of the present disclosure.

FIG. 5 is a top view of another semiconductor device, according to some embodiments of the present disclosure.

FIG. 6 is a top view of another semiconductor device, according to some embodiments of the present disclosure.

### DETAILED DESCRIPTION

The following disclosure provides many different embodiments, or examples, for implementing different features of the semiconductor device provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact. In addition, the present disclosure may repeat reference numerals and/or letters in the various examples. This repetition is for the purpose of simplicity and clarity, and does not in itself dictate a relationship between various embodiments and/or configuration discussed.

Furthermore, spatially relative terms, such as “beneath,” “below,” “lower,” “on,” “above,” “upper,” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some variations of some embodiments are discussed below. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of the present disclosure provide a semiconductor device and methods for forming the same. Through the disposition of an isolation region of the embodiments, the gate breakdown voltage can be enhanced. The electric field punch through and the breakdown generated from the gate end due to high voltage operation may be prevented, which in turn improves the electrical performance of the semiconductor device. In the following embodiments, elements of the semiconductor device are illustrated with a high-electron mobility transistor.

FIG. 1 is a top view of a semiconductor device, according to some embodiments of the present disclosure. According to some embodiments, a semiconductor device 1 includes a gate structure 140, a drain structure 160, and a source structure 170 on an epitaxial stack 120 over a substrate 100. As shown in FIG. 1, the semiconductor device 1 includes multiple semiconductor elements. With one element for example, the drain structure 160 and the source structure 170 thereof are on the opposite sides of the gate structure 140, respectively. Moreover, the drain structure 160 and the source structure 170 may, for example, extend in a first direction D1, and they are separated from the gate structure 140 in a second direction D2. Moreover, in the present embodiment, the gate structure 140 substantially extends in the first direction D1 and surrounds the source structure 170. Also, the gate structure 140 is separated from the source structure 170.

In the present embodiment, a device with inversely symmetrical configuration is illustrated. More specifically, the gate structure 140 includes, for example, a first gate portion 14-1, a second gate portion 14-2, and a bending portion 14-3, where the first gate portion 14-1 and the second gate portion 14-2 are positioned on the opposite sides of the source structure 170, respectively. The bending portion 14-3 connects the first gate portion 14-1 and the second gate portion 14-2. In FIG. 1, for example, the right side bending portion 14-3 is connected to the right side end portions of the first gate portion 14-1 and the second gate portion 14-2, while the left side bending portion 14-3 is connected to the left side end portions of the first gate portion 14-1 and the second gate portion 14-2 from a top view above the substrate 100. The first gate portion 14-1, the second gate portion 14-2, and the bending portion 14-3 thus constitute the gate structure 140 surrounding the source structure 170.

Moreover, the drain structure 160 at one side of the first gate portion 14-1 is a first drain structure 16-1, while the drain structure 160 at one side of the second gate portion 14-2 is a second drain structure 16-2. The first drain structure 16-1, the first gate portion 14-1, and the source structure 170 may serve respectively as the drain, the gate, and the source of a first device DE-1, while the source structure 170, the second gate portion 14-2, and the second drain structure 16-2 may serve respectively as the source, the gate, and the drain of a second device DE-2. FIG. 1 shows four devices for illustrative purpose, but the present disclosure is not limited to the quantity of the devices.

According to some embodiments, the semiconductor device 1 further includes an isolation region 200 that corresponds to an end region 140E of the gate structure 140. The isolation region 200 is positioned outside the end region 140E of the gate structure 140, and is not in contact with the gate structure 140. For example, the isolation region 200 is positioned outside the bending portion 14-3 of the gate structure 140.

In some embodiments, the isolation region 200 is a doped region that includes dopants for isolation materials, for example, nitrogen-containing dopants or the like. The isolation region 200 may be doped through an implantation process or the like. The isolation region 200 may electrically insulate neighboring semiconductor devices, and may prevent the short circuitry between the source and the drain of each semiconductor device. In the embodiments where the semiconductor device includes the high-electron mobility transistor element, a two-dimensional electron gas (2DEG) does not exist in the isolation region 200.

As shown in FIG. 1, the isolation region 200 extends in the second direction D2, and may be perpendicular to the extending direction (the first direction D1) of the drain structure 160 and the source structure 170 from a top view above the substrate 100. Moreover, in some embodiments, the isolation region 200 is separated from the end region 140E of the gate structure 140 by a distance of ds, for example.

Moreover, in some embodiments, there is a recess 200R on the edge of the isolation region 200 that is adjacent to each end region 140E of every gate structure 140. The recess 200R is complementary with the shape of the end region 140E of the gate structure 140 from a top view above the substrate 100. More specifically, in the embodiments where the gate structure 140 surrounds the source structure 170, the isolation region 200 is positioned outside the bending portion 14-3 of the gate structure 140 and extends along the outer edge of the bending portion 14-3. The recess 200R of the isolation region 200 is complementary with the shape of the bending portion 14-3.

Moreover, in some embodiments, the isolation region 200 extending in the second direction D2 has different widths in the first direction D1 from a top view above the substrate 100. For example, the distance between an edge 200s and an outer edge 200-OE of the isolation region 200 (in the first direction D1) is defined as a width W1, while the distance between the position on an inner edge 200-IE closest to the outer edge 200-OE and the outer edge 200-OE of the isolation region 200 (in the first direction D1) is defined as a width W2. The width W1 is larger than the width W2. Moreover, in the present example, the width W1 is, for example, the maximum width of the isolation region 200, while the width W2 is, for example, the minimum width of the isolation region 200.

Moreover, in some embodiments, the recess 200R of the isolation region 200 and the end region 140E of the gate structure 140 are separated by, for example, the distance ds. The distance ds surrounding outside the end region 140E of the gate structure 140 may be substantially equal or unequal, the present disclosure is not limited thereto. For example, the vertical distance (for example, parallel with the second direction D2) from the side of the gate structure 140 (extending along the first direction D1) to the isolation region 200 is a distance ds1, while the horizontal distance (for example, parallel with the first direction D1) from the tipping point of the end of the gate structure 140 to the isolation region 200 is a distance ds2. The distance ds1 and the distance ds2 may be equal or unequal.

Specifically, in some embodiments, the inner edge 200-IE of the isolation region 200 corresponds to (for example, is extended along) an outer edge 140-OE of the end region 140E of the gate structure 140 from a top view above the substrate 100, as shown in FIG. 1. Therefore, the inner edge 200-IE of the isolation region 200 and the outer edge 140-OE of the end region 140E of the gate structure 140 both have corresponding shapes (complementary with each other) from top view.

Moreover, in some embodiments, the isolation region 200 further corresponds to an end region 160E of the drain structure 160 and an end region 170E of the source structure 170. In the present embodiments (not limited), the isolation region 200 is positioned outside the end region 170E of the source structure 170. That is, the isolation region 200 is separated from the end region 170E of the source structure 170, and is not in contact with the source structure 170.

Moreover, there is a gap region 190 between the end region 170E of the source structure 170 and the end region 140E of the gate structure 140. In the present embodiments (not limited), the isolation region 200 is further positioned outside the gap region 190. That is, the isolation region 200 is separated from and not in contact with the gap region 190. Therefore, the isolation region 200 of the present embodiment is separated from the end region 140E of the gate structure 140, the source structure 170, and the gap region 190.

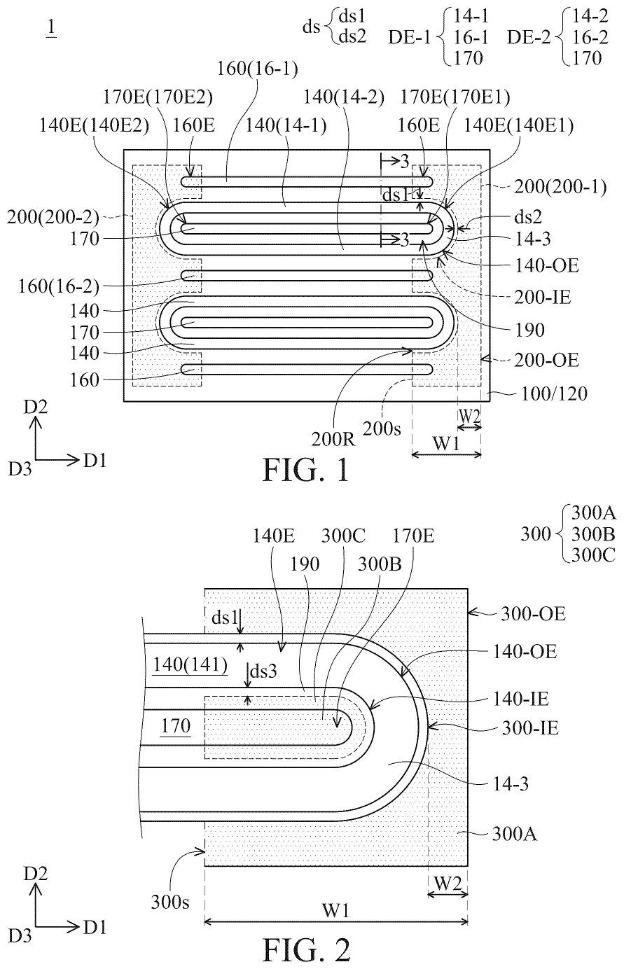

Moreover, in some embodiments, the semiconductor device includes the isolation region 200 adjacent to the opposite ends of the gate structure 140. More specifically, a first isolation region 200-1 is positioned outside a first end region 140E1 of the gate structure 140, while a second isolation region 200-2 is positioned outside a second end region 140E2 of the gate structure 140. The first isolation region 200-1 and the second isolation region 200-2 are disposed, for example, symmetrically with each other. In some embodiments, the first isolation region 200-1 and the second isolation region 200-2 are both not in contact with the gate structure 140, for example, not in contact with a doped compound semiconductor layer 141 (such as a p-type gallium nitride (pGaN) layer shown in FIG. 2), to be described in detail below.

In the above embodiments shown in FIG. 1, even though the isolation region 200 is separated from the end region 140E of the gate structure 140, the source structure 170, and the gap region 190 (for example, between the end region 170E of the source structure 170 and the end region 140E of the gate structure 140), the present disclosure is not limited thereto. The isolation region 200 may also include one or both of a portion corresponding to the end region 170E of the source structure 170 and a portion corresponding to the gap region 190.

FIG. 2 is a partial top view of another semiconductor device, according to some embodiments of the present disclosure. FIG. 2 only illustrates an enlarged top view of the end region 140E of the gate structure 140 and the end region 170E of the source structure 170 of one embodiment. Elements in FIG. 2 same or similar with those in FIG. 1 are designated with same or similar reference numbers, reference can be made to the descriptions of these elements in the above embodiments, and the details are not described again herein to avoid repetition.

In the present example, an isolation region 300 includes a portion 300A that is positioned outside and not in contact with the end region 140E of the gate structure 140. Also, the isolation region 300 further includes a portion 300B that corresponds to the end region 170E of the source structure 170, and a portion 300C that corresponds to the gap region 190 (for example, between the end region 170E of the source structure 170 and the end region 140E of the gate structure 140).

Moreover, in some embodiments, the portion 300A of the isolation region 300 may be separated from the outer edge 140-OE of the end region 140E of the gate structure 140 by the distance ds1. The portion 300C of the isolation region 300 may be (but not limited) separated from an inner edge 140-IE of the end region 140E of the gate structure 140 by a distance ds3, as shown in FIG. 2. That is, the portion 300C of the isolation region 300 only occupies a portion of the gap region 190 from a top view above the substrate 100. In other embodiments, the portion 300C of the isolation region 300 may correspond to the entire gap region 190.

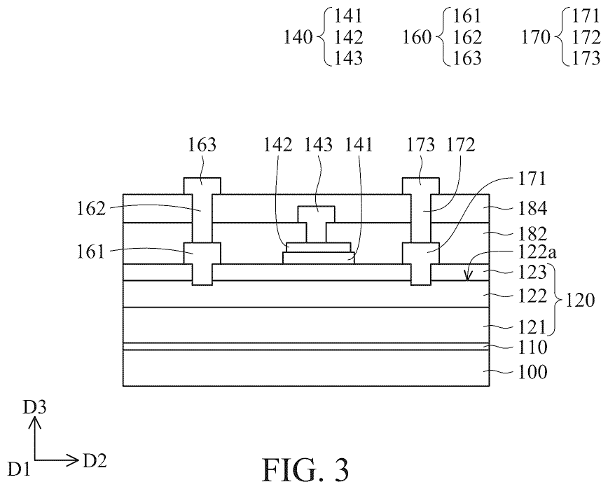

Moreover, in the present example, the isolation region 300 extending along the second direction D2 has different widths in the first direction D1. More specifically, the distance between an edge 300s and an outer edge 300-OE of the isolation region 300 (in the first direction D1) is the width W1, while the distance between the position on an inner edge 300-IE closest to the outer edge 300-OE and the outer edge 300-OE of the isolation region 300 (in the first direction D1) is the width W2, as shown in FIG. 3. The width W1 is larger than the width W2.

In some embodiments, when the isolation region 300 is doped with the implantation process, the portions outside the end region 140E of the gate structure 140, the end region 170E of the source structure 170, and the gap region 190 may be entirely or partially doped to form the isolation region 300, as shown in FIG. 2.

In the embodiment where the semiconductor device includes the high-electron mobility transistor element, the two-dimensional electron gas at the heterojunction between the channel layer 122 and the barrier layer 123 existed between the end regions 140E of the gate structures 140 of neighboring high-electron mobility transistor elements, as well as between the end region 140E of the gate structure 140 and the end region 160E of the drain structure 160 may be severed by the disposition of the isolation region 200. The short circuitry generated between the source structure 170 and the drain structure 160 is prevented. According to some embodiments, during the high voltage operation of the semiconductor device, the two-dimensional electron gas below the gate structure 140 (especially existed below the end region 140E) may change the electric field distribution of the end region 140E of the gate structure 140. In doing so, the breakdown voltage of the semiconductor device is enhanced, and the electrical performance of the semiconductor device is improved.

Additionally, in comparison with some conventional semiconductor devices with the gate breakdown voltage approximately 12V-13V, the gate breakdown voltage of the semiconductor device of the embodiments may be enhanced to approximately 14V-15V, according to some simulated experiment results. Therefore, the semiconductor device of the embodiments may effectively enhance the breakdown voltage. The above values are, of course, merely examples, and are not intended to limit the gate breakdown voltage of the present disclosure during application.

The following provides one of the configurations of the material layers with the gate, the source, the drain, and the like in the high-electron mobility transistor element, to illustrate the semiconductor device of some embodiments.

FIG. 3 is a cross-sectional view of a semiconductor device, according to some embodiments of the present disclosure. FIG. 3 is, for example, a cross-sectional view of the semiconductor device obtained along line 3-3 in FIG. 1. Reference may be made simultaneously to FIG. 1 and FIG. 3.

The semiconductor device includes the substrate 100, a seed layer 110 formed on the substrate 100, and the epitaxial stack 120 formed on the seed layer 110, according to some embodiments.

In some embodiments, the substrate 100 may be a doped (for example, with p-type dopants or n-type dopants) or undoped semiconductor substrate. For example, the substrate 100 may include an elemental semiconductor including silicon (Si) or germanium (Ge), a compound semiconductor including gallium arsenide (GaAs), gallium phosphide (GaP), indium phosphide (InP), indium arsenide (InAs), and/or indium antimonide (InSb), an alloy semiconductor including silicon germanium (SiGe) alloy, gallium arsenide phosphide (GaAsP) alloy, aluminum indium arsenide (AlInAs) alloy, aluminum gallium arsenide (AlGaAs) alloy, indium gallium arsenide (InGaAs) alloy, indium gallium phosphide (InGaP) alloy, and/or indium gallium arsenide phosphide (InGaAsP) alloy, or a combination thereof. In some embodiments, the substrate 100 may also be a semiconductor on insulator (SOI) substrate, for example, silicon on insulator or silicon germanium on insulator (SGOI). In other embodiments, the substrate 100 may be a ceramic substrate, for example, an aluminum nitride (AlN) substrate, a silicon carbide (SiC) substrate, an aluminum oxide (Al₂O₃) substrate (or referred to as a sapphire substrate), or the like. In some embodiments, the substrate 100 may include a ceramic base material, and a pair of barrier layers respectively disposed on the upper surface and the lower surface of the ceramic base material. The ceramic base material may include ceramic materials, and the ceramic materials include metallic inorganic materials. For example, the ceramic base materials may include silicon carbide, aluminum nitride, sapphire base materials, or the like. The aforementioned sapphire base materials may be aluminum oxide. FIG. 3 only illustrates a single layer of the substrate 100, for simplicity.

In some embodiments, materials of the seed layer 110 may include aluminum nitride, aluminum oxide, aluminum gallium nitride (AlGaN), silicon carbide, aluminum (Al), the like, or a combination thereof. In some embodiments, the formation of the seed layer 110 may include selective epitaxy growth (SEG) process, chemical vapor deposition (CVD) process, molecular-beam epitaxy (MBE) process, solid-phase epitaxial recrystallization (SPER) procedure after depositing the doped amorphous semiconductor (such as silicon), direct seed repost technique, or the like. Chemical vapor deposition process may be, for example, vapor phase epitaxy (VPE), low pressure chemical vapor deposition (LPCVD), ultra-high vacuum chemical vapor deposition (UHV-CVD), or the like. Moreover, the seed layer 110 may be a single layer or a multiple layer structure. FIG. 3 illustrates a single layer of the seed layer 110, for simplicity.

In the embodiment where the semiconductor device includes the high-electron mobility transistor element, the epitaxial stack 120 includes, for example, a buffer layer 121, a channel layer 122, and a barrier layer 123. As shown in FIG. 3, the buffer layer 121, the channel layer 122, and the barrier layer 123 are epitaxially formed on the seed layer 110 along a third direction D3.

In some embodiments, materials of the channel layer 122 include binary III-V group compound semiconductor materials, for example, III group nitrides. Materials of the channel layer 122 include, for example, gallium nitride (GaN), aluminum gallium nitride, aluminum nitride, gallium arsenide, indium gallium phosphide, aluminum gallium arsenide (AlGaAs), indium phosphide, indium aluminum arsenide (InAlAs), indium gallium arsenide, the like, or a combination thereof. In one example, the material of the channel layer 122 may be gallium nitride. Moreover, the channel layer 122 may be formed using molecular-beam epitaxy, hydride vapor phase epitaxy (HVPE), metal organic chemical vapor deposition (MOCVD), the like, or a combination thereof.

In some embodiments, the breakdown voltage of the high-electron mobility transistor element is mainly determined by the thickness of the channel layer (for example, the gallium nitride channel layer). For example, for every 1 μm increment on the thickness of the gallium nitride channel layer, the breakdown voltage of the high-electron mobility transistor may be increased by about 100V. During the epitaxial growth for forming the gallium nitride channel layer, a substrate with high thermal conductivity and high mechanical strength is required for depositing the gallium nitride material thereon, or it is possible to cause substrate warpage, or even fracture. In the embodiments where the substrate is made of aluminum nitride, in comparison with the silicon substrate, the aluminum nitride substrate has higher thermal conductivity and higher mechanical strength, thus a thicker gallium nitride channel layer may be formed on the aluminum nitride substrate. For example, the thickness of the gallium nitride channel layer formed on the surface of the silicon substrate may be about 2 μm to 4 μm, while the thickness of the gallium nitride channel layer formed on the surface of the aluminum nitride substrate may reach about 5 μm to 15 μm. The aforementioned values and ranges are merely exemplary, and are not intended to limit the material layers of the present disclosure.

Moreover, since there may be lattice variation or difference in thermal expansion coefficients between the channel layer 122 and the substrate 100, this may lead to strain generated at or close to the interface between the channel layer 122 and the substrate 100. Defects such as cracks or warpage may be readily formed in the channel layer 122. In some embodiments, the epitaxial stack 120 may include the buffer layer 121 between the substrate 100 and the channel layer 122, as shown in FIG. 3. The buffer layer 121 may alleviate the strain generated in the overlying channel layer 122, so the formation of the defects in the channel layer 122 may be prevented. In some embodiments, materials of the buffer layer 121 include aluminum nitride, gallium nitride, aluminum gallium nitride (AlₓGa₁₋ₓN, where 0<x<1), the like, or a combination thereof. In some embodiments, the buffer layer 121 may be formed from the epitaxial growth process, for example, hydride vapor phase epitaxy, molecular-beam epitaxy, metal organic chemical vapor deposition, the like, or a combination thereof.

Moreover, the buffer layer 121 may be a single layer structure or a multiple layer structure. Moreover, the buffer layer 121 may include a super-lattice buffer layer and/or a gradient buffer layer (not shown). The super-lattice buffer layer is disposed on the seed layer 110, and the gradient buffer layer is disposed on the super-lattice buffer layer. The dislocations within the substrate 100 may be effectively prevented from entering the channel region, and the crystalline quality of other overlying films and/or layers may be further enhanced. Furthermore, the super-lattice buffer layer and the gradient buffer layer may also be a multiple layer structure. For example, the super-lattice buffer layer may include many sets of alternating layers, and each set of the alternating layers includes at least one aluminum nitride layer and at least one aluminum gallium nitride layer (may be designated as AlₓGa₁₋ₓN according to different aluminum content, where 0<x<1) alternately arranged. The gradient buffer layer may include aluminum gallium nitride layers, designated as Al_{y}Ga_{1-y}N according to different aluminum content, where 0<y<1. FIG. 3 illustrates a single layer of the buffer layer 121, for simplicity.

In some embodiments, the barrier layer 123 is disposed on the channel layer 122. Materials of the barrier layer 123 may include ternary III-V group compound semiconductor, for example, III group nitrides. In some embodiments, the materials of the barrier layer 123 may be aluminum gallium nitride, aluminum indium nitride (AlInN), or a combination thereof. In other embodiments, the materials of the barrier layer 123 may be gallium nitride, aluminum nitride, gallium arsenide, indium gallium phosphide, aluminum gallium arsenide, indium phosphide, indium aluminum arsenide, indium gallium arsenide, the like, or a combination thereof. In some embodiments, the barrier layer 123 may have dopants, for example, n-type dopants or p-type dopants. Moreover, the barrier layer 123 may be formed on the channel layer 122 by epitaxial growth process, for example, molecular-beam epitaxy, metal organic chemical vapor deposition, hydride vapor phase epitaxy, the like, or a combination thereof.

In the embodiments where the semiconductor device includes the high-electron mobility transistor element, the channel layer 122 and the barrier layer 123 have different materials, thus the interface between the channel layer 122 and the barrier layer 123 (for example, at the top surface 122a of the channel layer 122) is a heterojunction. Due to the lattice mismatch between the channel layer 122 and the barrier layer 124, the stress is generated, leading to the piezoelectric polarization effect. Also, the bonding iconicity between the III group metals (for example, aluminum, gallium (Ga), or indium (In)) and nitrogen is stronger, which leads to the spontaneous polarization. Due to the difference in energy gap between the channel layer 122 and the barrier layer 123, as well as the aforementioned piezoelectric polarization and spontaneous polarization effects, the two-dimensional electron gas (not shown) may be formed on the heterojunction between the channel layer 122 and the barrier layer 123. In the embodiments where the semiconductor device includes the high-electron mobility transistor element, the two-dimensional electron gas may be utilized as the conductive carrier.

According to some embodiments, the semiconductor device further includes the gate structure 140, and the source structure 170 and the drain structure 160 that are positioned on the opposite sides of the gate structure 140, respectively.

In some embodiments, the gate structure 140 is on the barrier layer 123, and includes the doped compound semiconductor layer 141 and a gate electrode 142 on the doped compound semiconductor layer 141. The doped compound semiconductor layer 141 may suppress the generation of the two-dimensional electron gas generated below the subsequently formed gate electrode 142 thereon, in order to achieve the normally-off state of the semiconductor device.

The doped compound semiconductor layer 141 may include p-type dopants or n-type dopants. In some embodiments, the doped compound semiconductor layer 141 may include p-type doped III-V group semiconductor, for example, gallium nitride, aluminum gallium nitride, aluminum nitride, gallium arsenide, aluminum gallium arsenide, indium phosphide, indium aluminum arsenide, or indium gallium arsenide. In other embodiments, the doped compound semiconductor layer 141 may further include p-type doped II-VI group semiconductor, for example, cadmium silicide (CdS), cadmium telluride (CdTe), or zinc silicide (ZnS). Moreover, in some embodiments, the doped compound semiconductor layer 141 may be doped using lithium (Li), beryllium (Be), carbon (C), sodium (Na), magnesium (Mg), zinc (Zn), calcium (Ca), strontium (Sr), barium (Ba), radium (Ra), silver (Ag), gold (Au), or the like, allowing the doped compound semiconductor layer 141 to be p-type doped. In one example, the doped compound semiconductor layer 141 is a p-type gallium nitride layer. In some embodiments, the doped compound semiconductor layer 141 may be formed on the barrier layer 123 by, for example, atomic layer deposition (ALD), chemical vapor deposition, physical vapor deposition (PVD), epitaxial process, ion implantation, or in-situ doping process.

Moreover, the implantation process may be performed after the formation of the doped compound semiconductor layer 141, in order to form the isolation region 200 shown in FIG. 1 (not shown in FIG. 3), according to some embodiments. The isolation region 200 is not in contact with the doped compound semiconductor layer 141. In some embodiments, the dopants of the isolation region 200 is different from the dopants of the doped compound semiconductor layer 141.

In some embodiments, the gate electrode 142 may include conductive materials, for example, metals, metal nitrides, semiconductor materials, or the like. For example, metals may be gold, nickel (Ni), platinum (Pt), palladium (Pd), iridium (Ir), titanium (Ti), chromium (Cr), tungsten (W), aluminum, copper (Cu), the like, a combination thereof, or a multiple layer thereof. Metal nitrides may be molybdenum nitride (MoN), tungsten nitride (WN), titanium nitride (TiN), tantalum nitride (TaN), or the like. The semiconductor materials may be polysilicon or poly-germanium. The gate electrode 142 may be formed by deposition of the aforementioned conductive materials (for example, chemical vapor deposition, atomic layer deposition, or physical vapor deposition (such as sputtering or evaporation)), followed by patterning the conductive materials.

According to some embodiments, the semiconductor device further includes a first dielectric layer 182 on the barrier layer 123, and the doped compound semiconductor layer 141 and the gate electrode 142 are embedded within the first dielectric layer 182. The first dielectric layer 182 may include one or more dielectric materials, and may be a single layer or a multiple layer structures. A single layer of the first dielectric layer 182 is illustrated, for simplicity. The first dielectric layer 182 includes, for example, silicon oxide (SiO), silicon nitride (SiN), silicon oxynitride (SiON), tetra ethyl ortho silicate (TEOS), phosphosilicate glass (PSG), boron-doped phosphosilicate glass (BPSG), low-k dielectric materials, and/or the like. The low-k dielectric materials may include, but not limited to, fluorinated silica glass (FSG), hydrogen silsesquioxane (HSQ), carbon-doped silicon oxide, amorphous fluorinated carbon, parylene, bis-benzocyclobutene (BCB), or polyimide. In some embodiments, the first dielectric layer 182 may be formed using spin-on coating, chemical vapor deposition, physical vapor deposition, atomic layer deposition, high-density plasma chemical vapor deposition (HDP-CVD), the like, or a combination thereof.

Moreover, in some embodiments, the gate structure 140 further includes a gate metal layer 143. The gate metal layer 143 may be formed through a method similar to that of the gate electrode 142. The gate metal layer 143 may include the same or similar materials as those of the gate electrode 142. Materials of the gate metal layer 143 may include nickel silicide (NiSi), cobalt silicide (CoSi), tantalum carbide (TaC), tantalum silicon nitride (TaSiN), tantalum carbonitride (TaCN), titanium aluminum (TiAl), titanium aluminum nitride (TiAlN), metal oxides, metal alloys, the like, or a combination thereof.

Moreover, in some embodiments, a second dielectric layer 184 is formed on the first dielectric layer 182, and the second dielectric layer 184 covers the gate metal layer 143, as shown in FIG. 3. The process and materials of the second dielectric layer 184 may be the same or similar to those of the first dielectric layer 82, and the details are not described again herein to avoid repetition.

In some embodiments, the drain structure 160 disposed at one side of the gate structure 140 includes, for example, a drain electrode 161, a drain contact 162, and a drain metal layer 163. The drain contact 162 may be directly above and in contact with the drain electrode 161, and the drain metal layer 163 is electrically connected with the drain electrode 161 through the drain contact 162. Materials of the drain electrode 161 may be similar or the same with those of the gate electrode 142, reference can be made to the descriptions of the materials of the gate electrode 142, and the details are not described again herein to avoid repetition.

The formation of the drain electrode 161 is, for example, performing patterning process on the barrier layer 123 and a dielectric layer (not shown) on the barrier layer 123 to form openings in the barrier layer 123 and the dielectric layer. Then, the openings are filled with the conductive materials, and the planarization process (for example, chemical mechanical polish (CMP) or etch back process) is performed to remove excessive materials outside the openings. The drain electrode 161 can be formed.

Moreover, in some embodiments, the drain contact 162 and the drain metal layer 163 may include similar or the same materials. The drain contact 162 and the drain metal layer 163 may be formed using a process that is similar to that of the drain electrode 161 after the formation of the second dielectric layer 184. Moreover, for the drain contact 162 and the drain metal layer 163, reference can be made to the descriptions of the materials of the gate metal layer 143, and the details are not described again herein to avoid repetition.

In some embodiments, the source structure 170 disposed at another side of the gate structure 140 includes, for example, a source electrode 171, a source contact 172, and a source metal layer 173. The source contact 172 may be directly above and in direct contact with the source electrode 171, and the source metal layer 173 is electrically connected with the source electrode 171 through the source contact 172. Materials of the source electrode 171 may be similar or the same with those of the gate electrode 142, reference can be made to the descriptions of the materials of the gate electrode 142, and the details are not described again herein to avoid repetition. In some embodiments, the formation of the source electrode 171 is the same as that of the drain electrode 161, reference can be made to the above description. The source electrode 171 and the drain electrode 161 may be formed in the same process.

Moreover, in some embodiments, the source contact 172 and the source metal layer 173 may include similar or the same materials. The source contact 172 and the source metal layer 173 may be formed using a process that is similar to that of the source electrode 171 after the formation of the second dielectric layer 184. Moreover, for the source contact 172 and the source metal layer 173, reference can be made to the descriptions of the materials of the gate metal layer 143, and the details are not described again herein to avoid repetition.

Moreover, according to some embodiments, the drain structure 160 and the source structure 170 are positioned on the opposite sides of the gate structure 140, respectively. The drain electrode 161 of the drain structure 160 and the source electrode 171 of the source structure 170 are both penetrated through the barrier layer 123 and in contact with the channel layer 122.

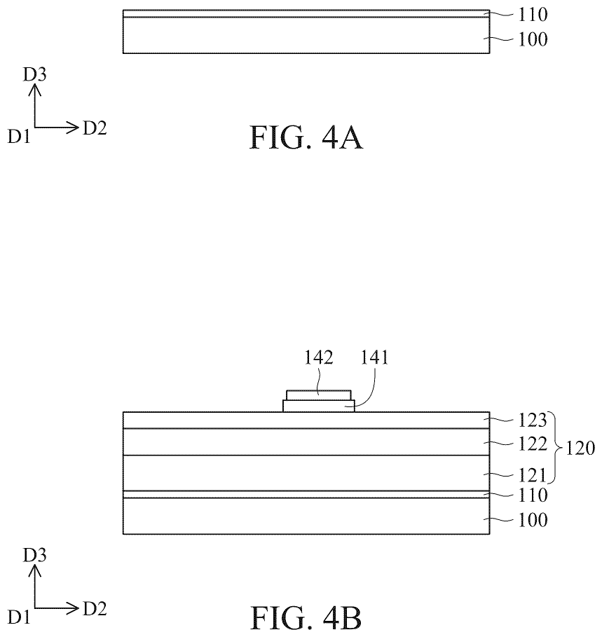

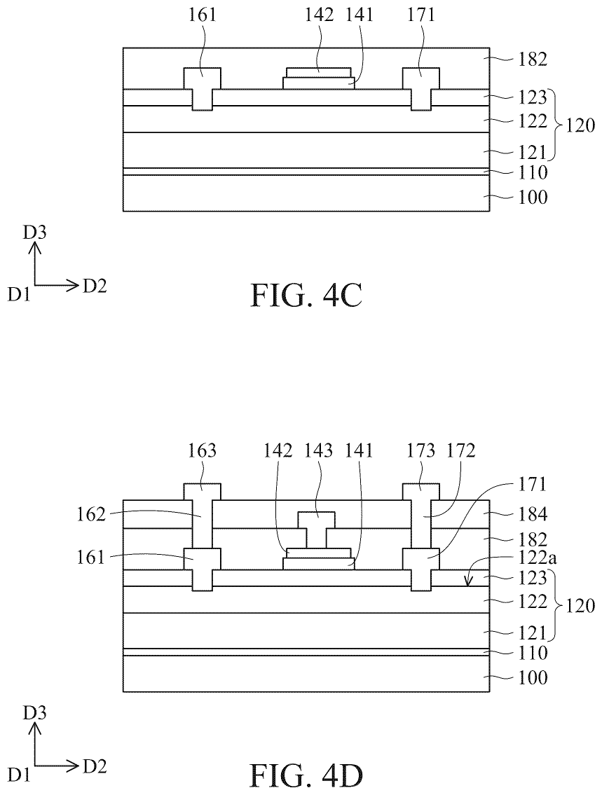

FIGS. 4A-4D are cross-sectional views of the semiconductor device illustrated in FIG. 3 at various intermediate stages, according to some embodiments of the present disclosure. Reference can be made simultaneously to FIG. 3 and FIGS. 4A-4D.

Referring to FIG. 4A, in some embodiments, the substrate 100 is provided, and the seed layer 110 is formed on the substrate 100. Materials and the formation of the substrate 100 and the seed layer 110 can be referred to the above description, and the details are not described again herein to avoid repetition.

Referring to FIG. 4B, the epitaxial stack 120 may then be formed on the seed layer 110 by epitaxial growth, in some embodiments. The epitaxial stack 120 sequentially includes, for example, the buffer layer 121, the channel layer 122, and the barrier layer 123. Materials and the formation of the buffer layer 121, the channel layer 122, and the barrier 123 may be referred to the above description, and the details are not described again herein to avoid repetition.

In some embodiments, the doped compound semiconductor layer 141 (for example, the p-type gallium nitride layer) is formed on the barrier layer 123, and the gate electrode 142 is formed on the doped compound semiconductor layer 141. Materials and the formation of the doped compound semiconductor layer 141 and the gate electrode 142 may be referred to the above description, and the details are not described again herein to avoid repetition.

According to some embodiments, a doped region is formed in the channel layer 122 by the implantation process after the formation of the doped compound semiconductor layer 141. The dope region includes, for example, nitrogen dopants for isolation materials. The isolation region of the embodiments is formed, for example, the isolation region 200 shown in FIG. 1 or the isolation region 300 shown in FIG. 2 are formed. The isolation region 200 or the isolation region 300 of the embodiments are not in contact with the doped compound semiconductor layer 141.

Moreover, in some embodiments, the gate structure 140 surrounds the source structure 170, and the doped isolation region 200 is positioned outside the bending portion 14-3 of the gate structure 140, as shown in FIG. 1. In some embodiments, the doped isolation region 300 may include the portion 300A that is positioned outside the bending portion 14-3, and the portion 300B and the portion 300C that are positioned inside the bending portion 14-3, as shown in FIG. 2.

In some embodiments, the dopants (for example, the nitrogen-containing dopants) of the isolation region and the dopants (for example, including the p-type dopants) of the doped compound semiconductor layer 141 are different. Moreover, the two-dimensional electron gas existed at the interface between the channel layer 122 and the barrier layer 123 is damaged and severed by dopants (for example, the nitrogen-containing dopants) in the isolation region of the embodiments (for example, the isolation region 200 and the isolation region 300). Therefore, the portion of the channel layer 122 in the isolation region of the embodiments does not have the two-dimensional electron gas as the conductive carriers, thus reaching the function of electrical insulation.

Referring to FIG. 4C, in some embodiments, the drain electrode 161 and the source electrode 171 are then respectively formed at the opposite sides of the stack constituted by the gate electrode 142 and the doped compound semiconductor layer 141. The first dielectric layer 182 is formed on the barrier layer 123. The first dielectric layer 182 covers the gate electrode 142, the doped compound semiconductor layer 141, the drain electrode 161, and the source electrode 171. Materials and the formation of the drain electrode 161, the source electrode 171, and the first dielectric layer 182 may be referred to the above description, and the details are not described again herein to avoid repetition.

Referring to FIG. 4D, in some embodiments, the second dielectric layer 184 is formed on the first dielectric layer 182. After the formation of the second dielectric layer 184, the drain contact 162, the drain metal layer 163, the source contact 172, and the source metal layer 173 may be formed by performing the process similar to the formation of the drain electrode 161 and the source electrode 171. Materials and the formation of the second dielectric layer 184 may be referred to those of the first dielectric layer 182. The positions, the materials, and the formation of the drain contact 162, the drain metal layer 163, the source contact 172, and the source metal layer 173 may also be referred to the above description, and the details are not described again herein to avoid repetition.

Even though the above embodiments are illustrated with the gate structure 140 continuously surrounding outside the source structure 170 as the example, but the present disclosure is not limited to the configuration of the gate structure.

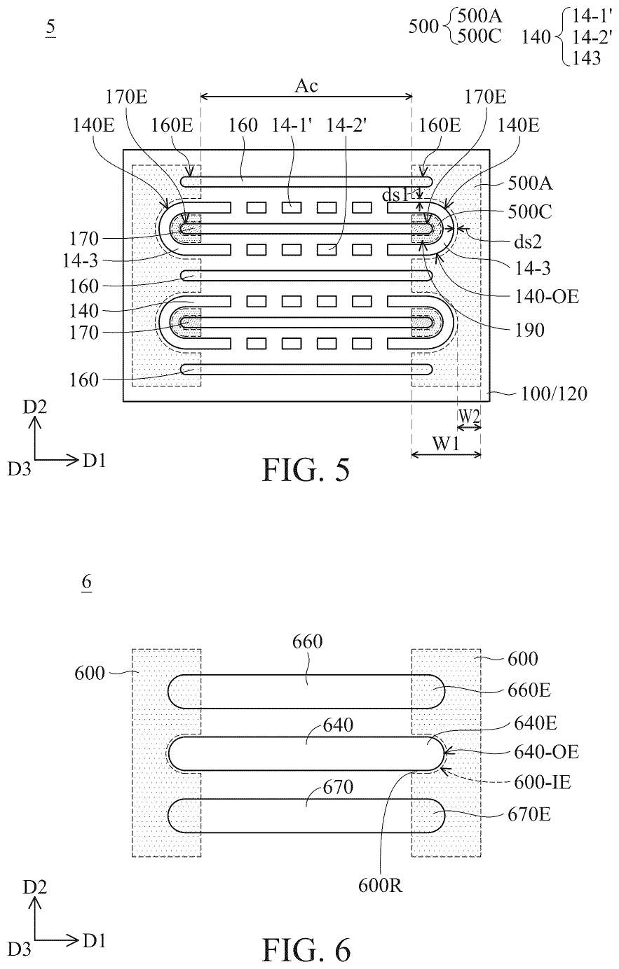

FIG. 5 is a top view of another semiconductor device, according to some embodiments of the present disclosure. Elements in FIG. 5 same or similar with those in FIG. 1 are designated with same or similar reference numbers, reference can be made to the descriptions of these elements in the above embodiments, and the details are not described again herein to avoid repetition.

The gate structure 140 of the semiconductor device 1 shown in FIG. 1 continuously surrounds outside the source structure 170 to form a closed ring from a top view above the substrate 100. Different from the semiconductor device 1 of FIG. 1, the gate structure 140 of a semiconductor device 5 shown in FIG. 5 includes a first gate portion 14-1′ and a second gate portion 14-2′ extending along the first direction D1, and the bending portion 14-3 connecting the first gate portion 14-1′ to the second gate portion 14-2′. The first gate portion 14-1′ and the second gate portion 14-2′ are positioned in the central area Ac between the two bending portions 14-3 from a top view above the substrate 100. In some embodiments, the first gate portion 14-1′ and the second gate portion 14-2′ includes separated segments, respectively.

Moreover, the configurations of the isolation regions of the semiconductor device 1 of FIG. 1 and the semiconductor device 5 of FIG. 5 are different. The isolation region 200 of FIG. 1 is positioned outside the bending portion 14-3 of the gate structure 140. An isolation region 500 of FIG. 5 includes a portion 500A outside the bending portion 14-3 of the gate structure 140, and a portion 500C corresponding to the gap region 190 (for example, between the end region 170E of the source structure 170 and the end region 140E of the gate structure 140).

Additionally, even though the above embodiments are illustrated with the gate structure 140 continuously surrounding outside the source structure 170 as an example, but the isolation region of the present disclosure may be applied to configurations of other gate structures, instead of limited to the gate structure 140 shown in FIG. 1 and FIG. 5.

FIG. 6 is a top view of another semiconductor device, according to some embodiments of the present disclosure. Elements in FIG. 6 same or similar with those in FIG. 1 are designated with same or similar reference numbers, reference can be made to the descriptions of these elements in the above embodiments, and the details are not described again herein to avoid repetition.

In some embodiments, a semiconductor device 6 includes a gate structure 640, a drain structure 660, and a source structure 670, as shown in FIG. 6. The drain structure 660 and the source structure 670 are positioned on the opposite sides of the gate structure 640, respectively. The gate structure 640, the drain structure 660, and the source structure 670 may, for example, extend in the first direction D1, and they are separated from each other in the second direction D2.

In some embodiment, the semiconductor device 6 further includes an isolation region 600 that corresponds to an end region 640E of the gate structure 640. The isolation region 600 is positioned outside the end region 640E of the gate structure 640, and is not in contact with the gate structure 640. Moreover, in some embodiments, the isolation region 600 and the end region 640E of the gate structure 640 may be separated by a distance.

As shown in FIG. 6, the isolation region 600 extends in the second direction D2, which may be perpendicular to the extending direction (the first direction D1) of the drain structure 660 and the source structure 670 from a top view above the substrate. Moreover, in some embodiments, the edge of the isolation region 600 that is close to the end region 640E of the gate structure 640 has a recess 600R. The recess 600R is complementary with the shape of the end region 640E of the gate structure 640. More specifically, an inner edge 600-IE of the isolation region 600 corresponds to the outer edge 640-OE of the end region 640E of the gate structure 640. For example, the inner edge 600-IE extends along the outer edge 640-OE.

Additionally, in some embodiments, the isolation region 600 further corresponds to an end region 670E of the source structure 670 and an end region 660E of the drain structure 660, but the present disclosure is not limited thereto. In other embodiments, the isolation region 600 may also be close to the end region 670E of the source structure 670 and the end region 660E of the drain structure 660, but the isolation region 600 is positioned outside and not in contact with the end region 670E and the end region 660E.

Moreover, in some embodiments, the isolation region 600 is a doped region that includes the dopants for isolation materials, for example, the nitrogen-containing dopants or the like. The isolation region 600 may be doped by the implantation process or the like. The isolation region 600 may prevent the short circuitry between the source and the drain of each semiconductor device. The two-dimensional electron gas existed below the end region 640E of the gate structure 640 may improve the breakdown voltage of the semiconductor device 6.

In summary, a semiconductor device and methods for forming the same are proposed according to the embodiments, where an isolation region corresponds outside and not in contact with a gate structure. For example, the isolation region is positioned outside and not in contact with a doped compound semiconductor layer (for example, a p-type gallium nitride layer) of the gate structure. In the application where the semiconductor device includes a high-electron mobility transistor element, the isolation region of the embodiments does not exist a two-dimensional electron gas. There exists the continuous two-dimensional electron gas below the gate structure of the embodiments (including below the end region of the gate structure). Therefore, during the high voltage operation of the semiconductor device of the embodiments, the continuous two-dimensional electron gas below the gate structure may change the electric field distribution of the end region and the gate structure. The breakdown voltage of the applied semiconductor device is enhanced, and the electrical performance of the semiconductor device is improved. Moreover, in the embodiments, the isolation region formed using an implantation process (for example, it is doped with the nitrogen-containing dopants) is not in contact with the gate structure, and thus there wouldn't be any damage to the relative material layer of the gate structure caused by the doping process. The gate structure has excellent profile and superior electrical performance. Therefore, in comparison with conventional semiconductor devices, the semiconductor device of the embodiments may prevent the electric field punch through and breakdown generated from the gate end under high voltage operation. Moreover, the methods for forming the semiconductor device proposed by the embodiments may manufacture the semiconductor device with improved electrical performance through non-complex process procedures that are compatible with the current process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a seed layer on the substrate;
an epitaxial stack on the seed layer;
a gate structure on the epitaxial stack;
a source structure and a drain structure on opposite sides of the gate structure, respectively; and
an isolation region corresponding to an end region of the gate structure, wherein the isolation region is positioned outside the end region of the gate structure, and the isolation region is not in contact with the gate structure.

2. The semiconductor device of claim 1, wherein the gate structure surrounds the source structure and is separated from the source structure from a top view above the substrate.

3. The semiconductor device of claim 1, wherein an inner edge of the isolation region corresponds to and extends along an outer edge of the end region of the gate structure.

4. The semiconductor device of claim 1, wherein an edge of the isolation region adjacent to the end region of the gate structure has a recess, and the recess is complementary with a shape of the end region.

5. The semiconductor device of claim 1, wherein the isolation region and the end region of the gate structure are separated by a distance.

6. The semiconductor device of claim 1, wherein the isolation region is a doped region, comprising a nitrogen-containing dopant.

7. The semiconductor device of claim 1, wherein the gate structure comprising:
a doped compound semiconductor layer on the epitaxial stack; and
a gate electrode on the doped compound semiconductor layer,
wherein the isolation region is not in contact with the doped compound semiconductor layer.

8. The semiconductor device of claim 7, wherein the isolation region and the doped compound semiconductor layer comprise dopants of different materials.

9. The semiconductor device of claim 1, wherein the gate structure comprising:
a first gate portion and a second gate portion on opposite sides of the source structure, respectively; and
a bending portion connecting the first gate portion to the second gate portion,
wherein the isolation region is positioned outside the bending portion.

10. The semiconductor device of claim 9, wherein the isolation region corresponds outside the bending portion and extends along an outer edge of the bending portion from a top view above the substrate.

11. The semiconductor device of claim 9, wherein the isolation region has a recess close to an edge of the bending portion of the gate structure, the recess is complementary with a shape of the bending portion.

12. The semiconductor device of claim 1, wherein the isolation region further comprises a portion positioned on an end region of the source structure.

13. The semiconductor device of claim 1, wherein the isolation region is positioned outside an end region of the source structure.

14. The semiconductor device of claim 1, wherein there is a gap region between an end region of the source structure and the end region of the gate structure, the gap region is a portion of the isolation region.

15. The semiconductor device of claim 1, wherein there is a gap region between an end region of the source structure and the end region of the gate structure, and the isolation region is positioned outside the gap region.

16. The semiconductor device of claim 1, wherein the source structure and the drain structure extend along a first direction, and are separated from the gate structure in a second direction,
wherein the isolation region extends along the second direction and has at least one recess close to the end region of the gate structure, and the recess is complementary with a shape of the end region of the gate structure.

17. The semiconductor device of claim 1, wherein the isolation region is a first isolation region positioned outside a first end region of the gate structure, and the semiconductor device further comprising:
a second isolation region positioned outside a second end region of the gate structure,
wherein the first end region and the second end region are opposite ends of the gate structure, and the first isolation region and the second isolation region are not in contact with the gate structure.

18. A method for forming a semiconductor device, comprising:
providing a substrate;
forming a seed layer on the substrate;
forming an epitaxial stack on the seed layer;
forming a gate structure on the epitaxial stack;
forming an isolation region corresponding to an end region of the gate structure, wherein the isolation region is positioned outside the end region of the gate structure and is not in contact with the gate structure from a top view above the substrate; and
forming a source structure and a drain structure on opposite sides of the gate structure, respectively.

19. The method of claim 18, wherein the source structure is formed surrounded by and separated from the gate structure from a top view above the substrate.

20. The method of claim 18, wherein an inner edge of the isolation region corresponds to and extends along an outer edge of the end region of the gate structure.

21. The method of claim 18, wherein an edge of the isolation region adjacent to the end region of the gate structure has a recess, and the recess is complementary with a shape of the end region.

22. The method of claim 18, wherein the isolation region is formed using a doping process, and the isolation region comprises a nitrogen-containing dopant.

23. The method of claim 18, wherein the isolation region is formed after forming the gate structure and before forming the source structure and the drain structure.

24. The method of claim 18, wherein the gate structure comprising:
a doped compound semiconductor layer; and
a gate electrode on the doped compound semiconductor layer,
wherein the isolation region is formed not in contact with the doped compound semiconductor layer.

25. The method of claim 24, wherein the isolation region is formed after forming the doped compound semiconductor layer.

26. The method of claim 24, wherein the doped compound semiconductor layer is a p-type gallium nitride (pGaN) layer.

27. The method of claim 18, wherein the isolation region is a first isolation region positioned outside a first end region of the gate structure, and the method further comprising:
forming a second isolation region outside a second end region of the gate structure,
wherein the first end region and the second end region are opposite ends of the gate structure, and the first isolation region and the second isolation region are not in contact with the gate structure.

28. The method of claim 27, wherein the first isolation region has a first recess close to the first end region, and the first recess is complementary with a shape of the first end region; and
the second isolation region has a second recess close to the second end region, and the second recess is complementary with a shape of the second end region.
